(19) United States
(12) Patent Application Publication
(10) Pub. No.: US 2026/0076169 A1
(43) Pub. Date: Mar. 12, 2026

(54) SEMICONDUCTOR STRUCTURE AND INTEGRATED ASSEMBLY

(71) Applicant: CXMT Corporation, Hefei City (CN)

(72) Inventors: SHIJIE BAI, Hefei City (CN); Bohui SHENG, Hefei City (CN); Depeng RAO, Hefei City (CN)

(73) Assignee: CXMT Corporation, Hefei City (CN)

(21) Appl. No.: 19/253,527

(22) Filed: Jun. 27, 2025

Related U.S. Application Data
(63) Continuation of application No. PCT/CN2025/087720, filed on Apr. 8, 2025.

(30) Foreign Application Priority Data
Sep. 10, 2024 (CN) 202411267637.7

(51) Int. Cl. H01L 23/528; H01L 23/00; H01L 23/522; H01L 25/18; H10B 80/00; H10D 80/30

(52) U.S. Cl. CPC H10W 20/43; H10B 80/00; H10W 20/42; H10W 90/00; H10D 80/30; H10W 72/926; H10W 80/701; H10W 90/297; H10W 90/792

(57) ABSTRACT

A semiconductor structure includes: a first surface and a second surface that are opposite to each other; a first and a second connection pads that are disposed on the first surface, and a third connection pad, a fourth connection pad, and a fifth connection pad that are disposed on the second surface; a memory cell region disposed between the first and the second surfaces, including a first and a second semiconductor devices that are arranged in a first direction, and a first connection portion, where the first connection pad and the fourth connection pad are connected to the first semiconductor device, the second connection pad and the fifth connection pad are connected to the second semiconductor device, the first connection portion is connected to at least one of the first semiconductor device and the second semiconductor device, and the first connection portion is connected to the third connection pad.

### CROSS-REFERENCE TO RELATED APPLICATIONS

This application is a continuation of International Patent Application No. PCT/CN2025/087720, filed on Apr. 8, 2025, which claims priority to Chinese Patent Application No. 202411267637.7, filed on Sep. 10, 2024. The disclosures of the above-referenced applications are hereby incorporated by reference in their entirety.

### BACKGROUND

A memory is configured to store data in modern computing architectures. A dynamic random access memory (DRAM) has advantages of simple structure, low costs, high speed, and the like, and is widely used as a main memory in personal computers, servers, and various electronic devices.

With continuously rapid growth of data, density increase of the DRAM is slowing down, resulting in a growing gap between memory demand and DRAM capacity. An increase in degree of integration by increasing packaging density to obtain a higher memory capacity has become an important target of integrated circuit fabrication at a current stage, and a memory with tight packaging is urgently to be developed.

### SUMMARY

Embodiments of the present disclosure relate to the technical field of semiconductors, and in particular to a semiconductor structure and an integrated assembly.

Embodiments of the present disclosure provide a semiconductor structure with a higher degree of integration.

According to an example implementation of the present disclosure, a semiconductor structure is provided. The semiconductor structure includes: a first surface and a second surface that are opposite to each other; a first connection pad and a second connection pad, disposed on the first surface; a third connection pad, a fourth connection pad, and a fifth connection pad, disposed on the second surface; and a memory cell region, where the memory cell region is disposed between the first surface and the second surface, the memory cell region includes a first semiconductor device and a second semiconductor device that are arranged in a first direction, the first connection pad and the fourth connection pad are connected to the first semiconductor device, the second connection pad and the fifth connection pad are connected to the second semiconductor device, the memory cell region further includes a first connection portion, the first connection portion is connected to at least one of the first semiconductor device and the second semiconductor device, and the first connection portion is connected to the third connection pad.

According to an example implementation of the present disclosure, an integrated assembly is provided. The integrated assembly includes: a first semiconductor structure, where the first semiconductor structure includes a first surface, a first connection pad and a second connection pad are disposed on the first surface, the first semiconductor structure further includes a memory cell region, the memory cell region is disposed below the first surface, the memory cell region includes a first semiconductor device and a second semiconductor device, the first connection pad is connected to the first semiconductor device, the second connection pad is connected to the second semiconductor device, and a first connection portion is disposed between the first semiconductor device and the second semiconductor device; and a second semiconductor structure, where the second semiconductor structure has a first bonding surface in bonding connection with the first surface of the first semiconductor structure, the second semiconductor structure includes a third semiconductor device and a fourth semiconductor device, the third semiconductor device and the first semiconductor device are connected to the first connection pad by using the first bonding surface, the fourth semiconductor device and the second semiconductor device are connected to the second connection pad by using the first bonding surface, the second semiconductor structure further has a common connection portion, the common connection portion is at least connected to the third semiconductor device or the fourth semiconductor device; where the first semiconductor structure further includes a second surface, a third connection pad, a fourth connection pad, a fifth connection pad, and a sixth connection pad are disposed on the second surface, the third connection pad is connected to the first connection portion, the fourth connection pad is connected to the first connection pad, the fifth connection pad is connected to the second connection pad, and the sixth connection pad is connected to the common connection portion.

### BRIEF DESCRIPTION OF DRAWINGS

The drawings herein, which are incorporated in and constitute a part of this specification, illustrate embodiments consistent with the embodiments of the present disclosure, and serve to explain the principles of the embodiments of the present disclosure together with this specification.

FIG. 1 is a schematic diagram of a semiconductor structure according to some embodiments of the present disclosure;

FIG. 2 is a schematic diagram of a semiconductor structure according to some embodiments of the present disclosure;

FIG. 3 is a schematic diagram of a semiconductor structure according to some embodiments of the present disclosure;

FIG. 4 is a schematic diagram of a semiconductor structure according to some embodiments of the present disclosure;

FIG. 5 is a schematic diagram of a semiconductor structure according to some embodiments of the present disclosure;

FIG. 6 is a schematic diagram of another semiconductor structure according to some embodiments of the present disclosure; and

FIG. 7 is a schematic structural diagram of an integrated assembly according to some embodiments of the present disclosure.

Through the drawings, clear embodiments of the present disclosure have already been shown, and are described in more detail below. These drawings and text descriptions are not intended to limit the scope of the concept of the embodiments of the present disclosure in any manner, but to describe the embodiments of the present disclosure for a person skilled in the art with reference to specific embodiments.

### DETAILED DESCRIPTION

The technical solutions in the embodiments of the present disclosure are clearly and completely described below with reference to the drawings in the embodiments of the present disclosure. It may be understood that specific embodiments described herein are merely intended to explain related disclosures, but are not intended to limit the present disclosure. In addition, it further needs to be noted that for ease of description, only related parts are shown in the drawings. Unless otherwise defined, all technical and scientific terms used in this specification have meanings the same as those commonly understood by a person skilled in the technical field of the present disclosure. The terms used in this specification are merely intended to describe the embodiments of the present disclosure, but are not intended to limit the present disclosure. The following descriptions relate to “some embodiments” describing a subset of all possible embodiments. However, it may be understood that “some embodiments” may be the same subset or different subsets of all the possible embodiments, and may be combined with each other when there is no conflict. It should be noted that the term “first\second\third” in the embodiments of the present disclosure is merely intended to distinguish between similar objects, and does not represent specific sorting for the objects. It may be understood that “first\second\third” may be interchanged for a specific sequence or order if allowed, so that the embodiments of the present disclosure described herein can be implemented in a sequence other than those shown or described herein.

The following describes the embodiments of the present disclosure in detail with reference to the drawings.

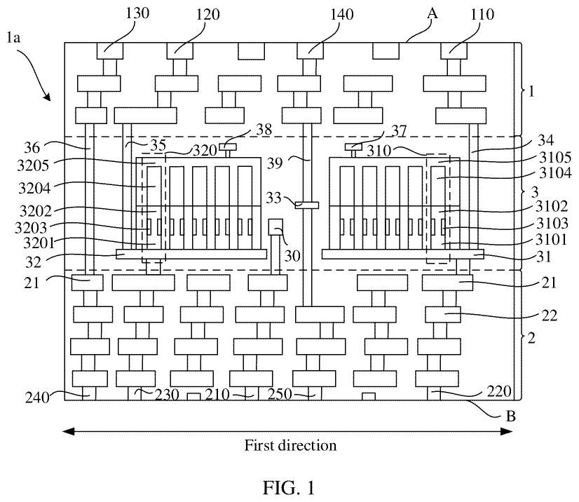

A semiconductor structure 1a is provided in FIG. 1. The semiconductor structure 1a includes a first surface A and a second surface B that are opposite to each other. A first connection pad 110 and a second connection pad 120 are disposed on the first surface A. A third connection pad 210, a fourth connection pad 220, and a fifth connection pad 230 are disposed on the second surface B.

The first surface A and the second surface B may be upper and lower surfaces, that are configured to be jointed with another semiconductor structure, of the semiconductor structure 1a, or may be used as independent upper and lower surfaces of the semiconductor structure 1a. The first connection pad 110 and the second connection pad 120 may each have a part that extends below the first surface A and a surface part exposed to the first surface A. The third connection pad 210, the fourth connection pad 220, and the fifth connection pad 230 may each have a part that extends below the second surface B and a surface part exposed to the second surface B. In some embodiments, the first connection pad 110 and the second connection pad 120 may be connection pads configured to be jointed with another semiconductor structure, and the third connection pad 210, the fourth connection pad 220, and the fifth connection pad 230 may be connection pads configured to be jointed with another semiconductor structure.

In some embodiments, the first connection pad 110, the second connection pad 120, the third connection pad 210, the fourth connection pad 220, and the fifth connection pad 230 may be conductive connection pads of the same material type, for example, conductive pads that contain copper, aluminum, and other metals, or alloys thereof. In some other embodiments, the first connection pad 110 and the second connection pad 120 may be conductive pads of the same material type, and the third connection pad 210, the fourth connection pad 220, and the fifth connection pad 230 are conductive pads of the same material type. However, the first connection pad 110 is different from the third connection pad 210. For example, the first connection pad 110 is a copper-containing conductive pad, and the third connection pad 210 is an aluminum-containing conductive pad.

In some embodiments, the first connection pad 110, the second connection pad 120, the third connection pad 210, the fourth connection pad 220, and the fifth connection pad 230 are functional connection pads. Non-functional connection pads are further disposed on the first surface A and the second surface B. The depth of the non-functional connection pad that extends below the first surface A and the second surface B is less than the extension depth of each functional connection pad, as shown in FIG. 1. In some embodiments, the non-functional connection pad may be disposed only on one surface of the semiconductor structure 1a. For example, the non-functional connection pad is disposed only on the second surface B. All connection pads disposed on the first surface A are functional connection pads. In some embodiments, the functional connection pads and the non-functional connection pads are uniformly distributed on each surface.

In some embodiments, by using a direction parallel to the first surface as a cross section, the first connection pad 110 and the second connection pad 120 may have the same or substantially the same width in this section. In some embodiments, the widths of the first connection pad 110 and the second connection pad 120 in this section may be different. For example, the width of the first connection pad 110 is greater than that of the second connection pad 120, or the width of the second connection pad 120 may be greater than that of the first connection pad 110. Similarly, the widths of the third connection pad 210, the fourth connection pad 220, and the fifth connection pad 230 may be the same or different from one another. In some embodiments, the maximum width of at least one of the first connection pad 110 and the second connection pad 120 is greater than that of at least one of the third connection pad 210, the fourth connection pad 220, and the fifth connection pad 230.

In some embodiments, a direction parallel to the first surface is used as a cross section. On this section, the first connection pad 110 and the second connection pad 120 have the minimum spacing therebetween, and every two connection pads of the third connection pad 210, the fourth connection pad 220, and the fifth connection pad 230 have the minimum spacing therebetween. The minimum spacing between the first connection pad 110 and the second connection pad is greater than that between every two connection pads of the third connection pad 210, the fourth connection pad 220, and the fifth connection pad 230.

In some embodiments, the minimum spacing between the first connection pad 110 and the second connection pad 120 includes the width of the first connection pad 110 and the distance between an outer edge of the first connection pad 110 and an outer edge of the second connection pad 120. In some other embodiments, the minimum spacing between the first connection pad 110 and the second connection pad 120 is the distance between an outer edge of the first connection pad 110 and an outer edge of the second connection pad 120.

The semiconductor structure 1a further includes a memory cell region 3. The memory cell region 3 is disposed between the first surface A and the second surface B. The memory cell region 3 includes a first semiconductor device 310 and a second semiconductor device 320. The first semiconductor device 310 and the second semiconductor device 320 are arranged in the first direction. The first direction may be a direction parallel to the first surface A, or may be a direction perpendicular to the first surface A. The first semiconductor device 310 and the second semiconductor device 320 are memory devices, for example, both are DRAM memory cells or NAND memory cells.

The memory cell region 3 further includes a first connection portion 30. The first connection portion 30 is configured to connect to at least one of the first semiconductor device 310 and the second semiconductor device 320. For example, in some embodiments, the first connection portion 30 is connected to both the first semiconductor device 310 and the second semiconductor device 320, that is, the first connection portion 30 may be a common connection portion between the first semiconductor device 310 and the second semiconductor device 320, as shown in FIG. 1. In this case, the first semiconductor device 310 and the second semiconductor device 320 are connected to the third connection pad 210 by using the first connection portion 30. In some embodiments, the first direction is a direction perpendicular to the first connection portion.

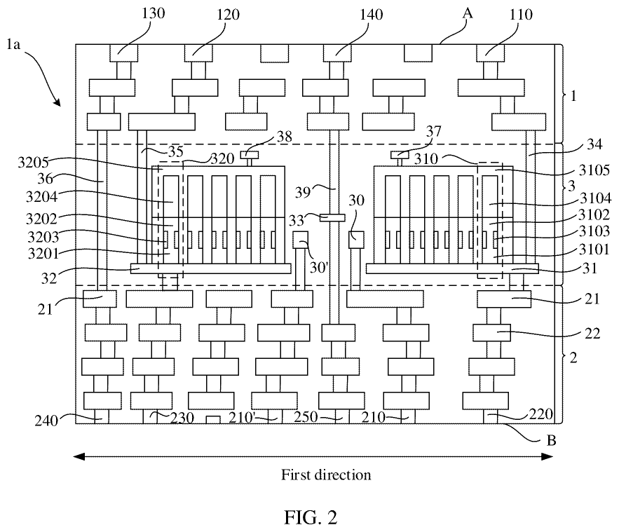

In some embodiments, the first connection portion 30 may alternatively be connected to the first semiconductor device 310 or the second semiconductor device 320 alone. As shown in FIG. 2, FIG. 2 shows a semiconductor structure 1a in which the first connection portion 30 is connected to the first semiconductor device 310 alone and the second semiconductor device 320 is connected to another connection portion 30′ alone. In this case, the first semiconductor device 310 is connected to the third connection pad 210 by using the first connection portion 30, and the second semiconductor device 320 is connected to another connection pad 210′ on the second surface B by using the another connection portion 30′.

A region between the first semiconductor device 310 and the second semiconductor device 320 is a region in which an insulating dielectric layer is disposed, and a semiconductor device may not be disposed in this region. The first connection portion 30 may be located in the region between the first semiconductor device 310 and the second semiconductor device 320, or may be located on one side of the first semiconductor device 310 or the second semiconductor device 320. The first connection portion 30 and the another connection portion 30′ may be respectively located on one side of the first semiconductor device 310 or the second semiconductor device 320, or may be located between the first semiconductor device 310 and the second semiconductor device 320. The first semiconductor device 310 further has one end connected to the first connection pad 110 and the fourth connection pad 220, and the second semiconductor device 320 further has one end connected to the second connection pad 120 and the fifth connection pad 230. In the semiconductor structure 1a, the first semiconductor device 310 and the second semiconductor device 320 form connection channels by using each connection pad disposed on the first surface A and the second surface B respectively, and the first semiconductor device 310 and the second semiconductor device 320 may be arranged and designed more flexibly by using the additionally added connection channel, thereby reducing the area of the memory cell region and providing a more compact semiconductor structure.

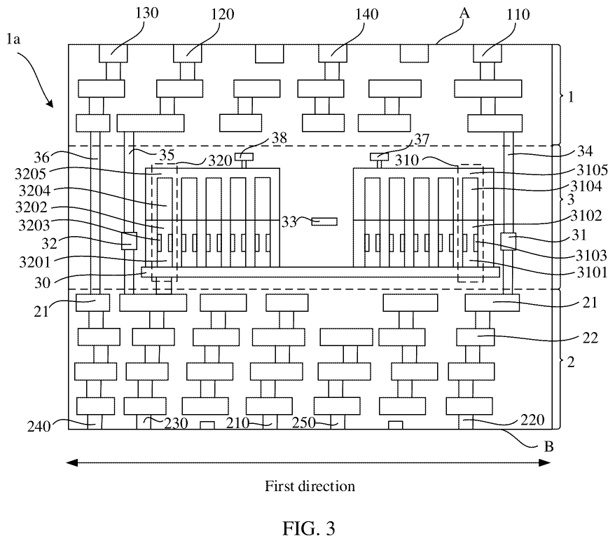

In some embodiments, the first connection portion 30 is disposed closer to the second surface B. Referring to FIG. 3, different from FIG. 1 and FIG. 2, in the semiconductor structure 1a shown in FIG. 3, the first connection portion 30 is disposed closer to the second surface B than the first connection portion 30 in FIG. 1 and FIG. 2. The first connection portion 30 is connected to both the first semiconductor device 310 and the second semiconductor device 320, and is located in a region of the memory cell region 3 close to a bottom.

In some embodiments, the first semiconductor device 310 and the second semiconductor device 320 may be DRAM memory device cells. FIG. 1 to FIG. 3 show schematic structural diagrams of the first semiconductor device 310 and the second semiconductor device 320 using the same DRAM memory device cell. Basic cells include a transistor and a capacitor. The transistor in the first semiconductor device 310 includes a source 3102 and a drain 3101. The source 3102 and the drain 3101 are arranged in the vertical direction. There is a channel region between the source 3102 and the drain 3101. A gate 3103 disposed around the channel region is disposed on a periphery of the channel region. Similarly, the transistor in the second semiconductor device 320 includes a source 3202 and a drain 3201 that are arranged in the vertical direction, and a channel region located between the source 3202 and the drain 3201. A gate 3203 disposed around the channel region is disposed on a periphery of the channel region. The capacitor in the first semiconductor device 310 includes an electrode portion 3104 connected to the source 3102, and the capacitor in the second semiconductor device 320 also includes an electrode portion 3204 connected to the source 3202. The first semiconductor device 310 further includes an electrode portion 3105. The electrode portion 3104 and the electrode portion 3105 constitute upper and lower electrodes of the capacitor in the first semiconductor device 310. The second semiconductor device 320 further includes an electrode portion 3205. The electrode portion 3204 and the electrode portion 3205 constitute upper and lower electrodes of the capacitor in the second semiconductor device 320. In some embodiments, as shown in FIG. 1, the first connection portion 30 is connected to the gate 3103 of the first semiconductor device 310 and the gate 3203 of the second semiconductor device 320. In some embodiments, as shown in FIG. 2, the first connection portion 30 is connected to the gate 3103 of the first semiconductor device 310, and the connection portion 30′ is connected to the gate 3203 of the second semiconductor device 320. In some embodiments, as shown in FIG. 3, the first connection portion 30 is connected to the drain 3101 of the first semiconductor device 310 and the drain 3201 of the second semiconductor device 320. In some embodiments, the connection portion connected to the gate may be referred to as a word line, and the connection portion connected to the drain may be referred to as a bit line.

Still referring to FIG. 1 to FIG. 3, in some embodiments, the semiconductor structure 1a further includes an interconnection layer 1 disposed adjacent to the first surface A and a redistribution layer 2 disposed adjacent to the second surface B. The first connection pad 110 and the second connection pad 120 are respectively connected to the first semiconductor device 310 and the second semiconductor device 320 by using the interconnection layer 1. The fourth connection pad 220 and the fifth connection pad 230 are respectively connected to the first semiconductor device 310 and the second semiconductor device 320 by using the redistribution layer 2. The third connection pad 210 is connected to the first connection portion 30 by using the redistribution layer. The interconnection layer 1 consists of at least one layer of conductive interconnection lines, and the redistribution layer 2 consists of at least one conductive redistribution layer. For example, the interconnection layer 1 may include two layers of conductive interconnection lines. The layers of conductive interconnection lines are interconnected by using inter-layer through holes. The conductive interconnection lines are interconnected to the first connection pad 110 and the second connection pad 120 by using inter-layer through holes. The redistribution layer 2 may include two or more conductive redistribution layers, for example, may include four conductive redistribution layers. The conductive redistribution layers are interconnected by using inter-layer through holes. The third connection pad 210, the fourth connection pad 220, and the fifth connection pad 230 are interconnected to the conductive redistribution layers by using inter-layer through holes. In some embodiments, the metal density in the redistribution layer 2 is greater than that in the interconnection layer 1. The metal density refers to a volume proportion or a mass proportion of a metal component in a specific volume, that is, the metal density of the interconnection layer refers to a volume proportion or a mass proportion of metal interconnection in the interconnection layer, and the metal density of the redistribution layer refers to a volume proportion or a mass proportion of metal wiring in the redistribution layer. In these embodiments, an interconnection layer and a redistribution layer that have different metal densities are respectively disposed on two opposite sides of the memory cell region, so that not only a requirement of interconnection densities on different surfaces can be met, but also warping of the semiconductor structure can be improved, so that deformation between a middle part and an edge part of the first surface and the second surface of the semiconductor structure is reduced, and subsequent package integration is used.

In the embodiments of the present disclosure, there is no clear distinction among the interconnection layer 1, the memory cell region 3, and the redistribution layer 3, and there may be overlapping regions between every two of the interconnection layer 1, the memory cell region 3, and the redistribution layer 3. The present disclosure is not limited to the structures shown in FIG. 1 to FIG. 3.

Still referring to FIG. 1 to FIG. 3, the semiconductor structure 1a further includes a second connection portion 31 and a third connection portion 32. The second connection portion 31 is connected to one end of the first semiconductor device 310. The third connection portion 32 is connected to one end of the second semiconductor device 320. The first connection portion 30 is connected to the other ends of the first semiconductor device 310 and the second semiconductor device 320. The second connection portion 31 may be a common connection portion at one end of the first semiconductor device 310, and the third connection portion 32 may be a common connection portion at one end of the second semiconductor device 320. In some embodiments, as shown in FIG. 1, the first connection portion 30 is connected to both the gate of the first semiconductor device 310 and the gate of the second semiconductor device 320, the second connection portion 31 is connected to the drain 3101 of the first semiconductor device 310, and the third connection portion 32 is connected to the drain 3201 of the second semiconductor device 320. In some embodiments, as shown in FIG. 2, the first connection portion 30 is connected to the gate 3103 of the first semiconductor device 310, the second connection portion 31 is connected to the drain 3101 of the first semiconductor device 310, and the third connection portion 32 is connected to the drain 3201 of the second semiconductor device 320. In some embodiments, as shown in FIG. 3, the first connection portion 30 is connected to both the drain 3101 of the first semiconductor device 310 and the drain 3201 of the second semiconductor device 320, the second connection portion 31 is connected to the gate 3103 of the first semiconductor device 310, and the third connection portion 32 is connected to the gate 3203 of the second semiconductor device 320. In this case, the first connection portion 30 is disposed closer to the second surface B than the second connection portion 31 and the third connection portion 32. A connection relationship between each connection portion and each semiconductor device is not limited thereto. In some other embodiments, there may be another connection manner. In some embodiments, the first direction is a direction parallel to the second connection portion 31 and the third connection portion 32.

The first connection portion 30, the second connection portion 31, and the third connection portion 32 are isolated from each other, that is, an insulating dielectric layer is disposed between the connection portions, so as to prevent the connection portions from being short-circuited. The second connection portion 31 is connected to the first connection pad 110, so as to implement connection between the first semiconductor device 310 and the first connection pad 110. The third connection portion 32 is connected to the second connection pad 120, so as to implement connection between the second semiconductor device 320 and the second connection pad 120.

In some embodiments, the second connection portion 31 is interconnected to the first connection pad 110 by using an interconnection structure 34, and the third connection portion 32 is interconnected to the second connection pad 120 by using an interconnection structure 35. The interconnection structure 34 and the interconnection structure 35 may be conductive structures that vertically pass through the memory cell region 3, or may be conductive structures that are interconnected by using multi-layer wiring.

Still referring to FIG. 1 to FIG. 3, the redistribution layer 2 further includes a first redistribution layer 21 disposed adjacent to the memory cell region 3, and the first connection portion 30, the second connection portion 31, and the third connection portion 32 are connected to the first redistribution layer 21. The first redistribution layer 21 is interconnected to each connection portion by using an inter-layer through hole. In some embodiments, the height of the inter-layer through hole connected between the first redistribution layer 21 and the first connection portion 30 is greater than that of the inter-layer through hole connected between the first redistribution layer 21 and the second connection portion 31 or the third connection portion 32.

In some embodiments, in the direction parallel to the first surface A, the second connection portion 31 and the third connection portion 32 have different lengths.

Still referring to FIG. 1 to FIG. 3, in some embodiments, a sixth connection pad 130 is further disposed on the first surface A, a seventh connection pad 240 is further disposed on the second surface B, and the sixth connection pad 130 is connected to the seventh connection pad 240. In some embodiments, the sixth connection pad 130 and the seventh connection pad 240 are connected by using an interconnection structure 36 that runs through the memory cell region 3. In some embodiments, the interconnection structure 36 may be multiple layers of metal conductors disposed in the memory cell region 3. In some embodiments, the interconnection structure 36 is connected to the first redistribution layer 21, and the seventh connection pad 240 is connected to the interconnection structure 36 by using the first redistribution layer 21.

Still referring to FIG. 1 to FIG. 3, in some embodiments, the memory cell region 3 further includes a fourth connection portion 33, and the fourth connection portion 33 is located in the region between the first semiconductor device 310 and the second semiconductor device 320. The region between the first semiconductor device 310 and the second semiconductor device 320 may be a region in which an insulating dielectric layer is disposed, and the region does not include a semiconductor device. In some embodiments, the fourth connection portion 33 is disposed closer to the interconnection layer 1 than the first connection portion 30. In some other embodiments, a top surface of the fourth connection portion 33 is higher than those of the source 3102 of the first semiconductor device 310 and the source 3202 of the second semiconductor device 320, but lower than those of the electrode portion 3104 and the electrode portion 3204. In some other embodiments, the top surface of the fourth connection portion 33 is not higher than those of the source 3102 of the first semiconductor device 310 and the source 3202 of the second semiconductor device 320.

In some embodiments, the electrode portion 3104 of the first semiconductor device 310 and/or the electrode portion 3204 of the second semiconductor device 320 may be directly connected to the source 3102 of the first semiconductor device 310 and/or the source 3202 of the second semiconductor device 320 or be interconnected thereto by using a contact plug. In some embodiments, materials of the electrode portion 3104 of the first semiconductor device 310 and/or the electrode portion 3204 of the second semiconductor device 320 include polycrystalline silicon, a metal (such as tungsten (W), copper (Cu), or aluminum (Al)), a metal compound (such as titanium nitride (TiN) or tantalum nitride (TaN)), or a silicide (such as cobalt silicide or nickel silicide). Materials of the source 3102 of the first semiconductor device 310 and/or the source 3202 of the second semiconductor device 320 include polycrystalline silicon, doped monocrystalline silicon, metal silicide, and the like.

In some embodiments, the fourth connection portion 33 and the electrode portion 3104 of the first semiconductor device 310 and/or the electrode portion 3204 of the second semiconductor device 320 are formed in the same process step, and are isolated from each other. In some embodiments, the fourth connection portion 33 has the same material as the electrode portion 3104 and the electrode portion 3204.

In some embodiments, the fourth connection portion 33 and the source 3102 of the first semiconductor device 310 and/or the source 3202 of the second semiconductor device 320 are formed in the same processing process step, and are isolated from each other. In some embodiments, the fourth connection portion 33 has the same material as the source 3102 and the source 3202, for example, has a silicon-containing metal compound.

In some embodiments, the fourth connection portion 33 may be formed in the process step of forming the contact plug.

In some embodiments, an eighth connection pad 140 is further disposed on the first surface A, and a ninth connection pad 250 is further disposed on the second surface B. The eighth connection pad 140 and the ninth connection pad 250 are connected to the fourth connection portion 33, so as to form a channel from the first surface A to the second surface B. In some embodiments, as shown in FIG. 1 and FIG. 2, the fourth connection portion 33 is connected to the eighth connection pad 140 and the ninth connection pad 250 by using the interconnection structure 39. In some embodiments, as shown in FIG. 3, because FIG. 3 has a wiring design different from those in FIG. 1 and FIG. 2, the interconnection structure 39 connected to the fourth connection portion 33 and the ninth connection pad 250 is not shown in this section.

In these embodiments, a fourth connection portion is disposed in the region between the first semiconductor device and the second semiconductor device, which can simplify a process of forming a connection channel between the eighth connection pad 140 and the ninth connection pad 250, reduce a process difficulty, and improve a yield.

The first semiconductor device 310 and the second semiconductor device 320 further include a connection portion 37 and a connection portion 38 respectively. The connection portion 37 and the connection portion 38 may be respectively located above the first semiconductor device 310 and the second semiconductor device 320. The connection portion 37 and the connection portion 38 are respectively connected to the electrode portion 3105 in the first semiconductor device 310 and the electrode portion 3205 of the second semiconductor device 320. The connection portion 37 and the connection portion 38 may be connected or not connected to each other. In some embodiments, the fourth connection portion 33 is not connected to the connection portion 37 or the connection portion 38. In some other embodiments, the fourth connection portion is respectively connected to the first semiconductor device 310 and the second semiconductor device 320 by using the connection portion 37 and the connection portion 38, or is connected to both the first semiconductor device 310 and the second semiconductor device 320 by using the connection portion 37 and the connection portion 38.

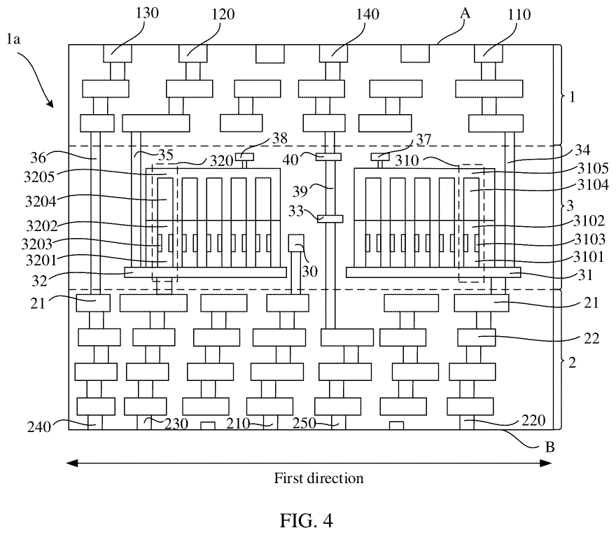

In some embodiments, the semiconductor structure 1a further includes a fifth connection portion 40. As shown in FIG. 4, the fifth connection portion 40 is disposed closer to the interconnection layer 1 than the fourth connection portion 40. The fifth connection portion 40 is connected to the fourth connection portion 33 by using the interconnection structure 39, that is, a conductive channel formed between the eighth connection portion 140 and the ninth connection portion 250 includes the fourth connection portion 33 and the fifth connection portion 40. In some embodiments, the fifth connection portion 40 may not be connected to the connection portion 37 and the connection portion 38, may be connected to the connection portion 37 and the connection portion 38 alone, or may be connected to both the connection portion 37 and the connection portion 38. The fifth connection portion 40 may be located in a region between the connection portion 37 and the connection portion 38, and the fifth connection portion 40 may be fabricated by using the same metal process with the connection portion 37 and the connection portion 38.

In some embodiments, the redistribution layer 2 further includes a second redistribution layer 22. The second redistribution layer 22 is disposed closer to the second surface B than the first redistribution layer 21. The fourth connection portion 33 is connected to the second redistribution layer 22 by using the interconnection structure 39. The fourth connection portion 33 may be directly connected to the second redistribution layer 22 by using the interconnection structure 39, or may be connected to the second redistribution layer 22 by using the first redistribution layer 21.

The first redistribution layer 21 and the second redistribution layer 22 may be conductive layers disposed in the insulating dielectric layer. Between the first redistribution layer 21 and the second redistribution layer 22, a signal is transmitted between the first redistribution layer 21 and the second redistribution layer 22 by using a through hole structure at a specific location. In some embodiments, the first redistribution layer 21 and the second redistribution layer 22 are formed by using a metal process technology, such as a damascene process. The first redistribution layer 21 and the second redistribution layer 22 may be one or a combination of metals such as copper, a copper alloy, tungsten, a tungsten alloy, aluminum, and an aluminum alloy.

The redistribution layer 2 further includes another conductive redistribution layer disposed between the second redistribution layer 22 and the second surface B. The quantity of other conductive redistribution layers may be 1, 2, 3, 4, or another quantity.

In some embodiments, the memory cell region in the semiconductor structure 1a includes a plurality of first semiconductor devices 310 and a plurality of second semiconductor devices 320. With reference to FIG. 1 to FIG. 4 and FIG. 5, the plurality of first semiconductor devices 310 constitute a first memory cell array 4, and the plurality of second semiconductor devices 320 constitute a second memory cell array 5. The first memory cell array 4 and the second memory cell array 5 are arranged at an interval. The first memory cell array 4 includes a plurality of first semiconductor devices 310 arranged in the first direction and a plurality of first semiconductor devices 310 arranged in the second direction. The second memory cell array 5 includes a plurality of second semiconductor devices 320 arranged in the first direction and a plurality of second semiconductor devices 320 arranged in the second direction. The first direction and the second direction are perpendicular to each other, and both the first direction and the second direction may be parallel to the first surface A and the second surface B.

In some embodiments, the first memory cell array 4 includes a first connection portion 30 connected to the plurality of first semiconductor devices 310, and the first connection portion 30 is connected to one end of each of the plurality of first semiconductor devices in the second direction. In the first direction, there is a second connection portion 31 between the plurality of first semiconductor devices 310 in the first memory cell array 4, and the second connection portion 31 is connected to one end of each of the plurality of first semiconductor devices 310 in the first direction. Similarly, in the second memory cell array 5, one end of each of the plurality of second semiconductor devices 320 in the second direction is connected to another connection portion 30′, and one end of each of the plurality of second semiconductor devices 320 in the first direction is connected to the third connection portion 32.

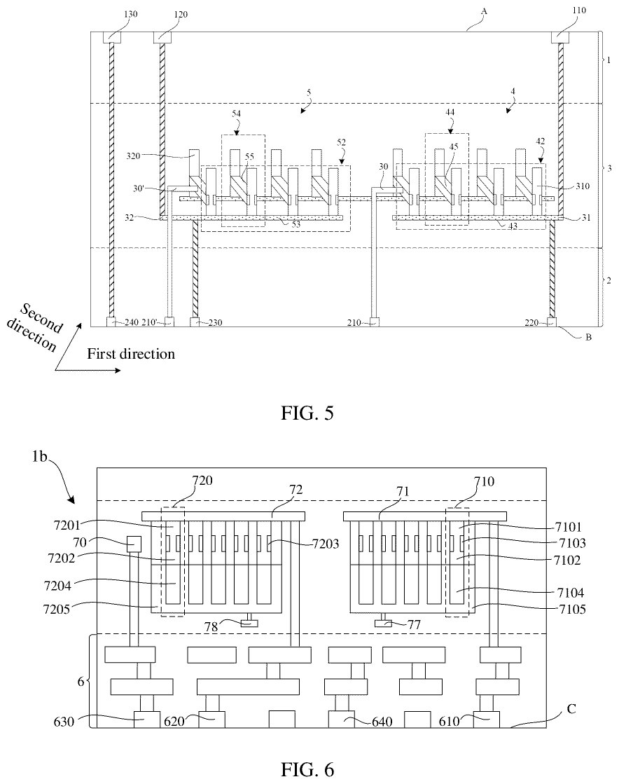

In some embodiments, referring to FIG. 3, the first connection portion 30 may further be connected to one end of each of the plurality of first semiconductor devices 310 and one end of each of the plurality of second semiconductor devices 320 in the first direction. In this case, the second connection portion 31 and the third connection portion 33 are respectively connected to the plurality of first semiconductor devices 310 in the second direction and the plurality of second semiconductor devices 320 in the second direction. Connection relationships between the first connection portion 30, the second connection portion 31, and the third connection portion 32 and the semiconductor devices in each memory cell array are not limited to a case shown in FIG. 5.

In the foregoing embodiment, the plurality of first semiconductor devices 310 and the plurality of second semiconductor devices 320 respectively form a connection channel that extends to the second surface B by using the first connection portion 30 and the third connection pad 210, and the connection portion 30′ and the connection pad 210′. The plurality of first semiconductor devices 310 and the plurality of second semiconductor devices 320 respectively form a connection channel that extends from the first surface A to the second surface B by using the second connection portion 31 and the third connection portion 32. For example, the second connection portion 31 is connected to the first connection pad 110 in the first surface A and the fourth connection pad 220 in the second surface B, so as to establish a connection channel, that extends between the first surface A and the second surface B, of the first semiconductor device 310. The third connection portion 32 is connected to the second connection pad 120 in the first surface A and the fifth connection pad 230 in the second surface B, so as to establish a connection channel, that extends between the first surface A and the second surface A, of the second semiconductor device 320. With this design, each semiconductor device in the memory cell array may be arranged and designed more flexibly, thereby further reducing the area of the memory cell region, and providing a more compact semiconductor structure.

Still referring to FIG. 5, in the first memory cell array 4, the plurality of first semiconductor devices 310 arranged in the first direction form a plurality of first sub-columns 42. The same end of the plurality of first semiconductor devices 310 in each of the first sub-columns 42 is connected to a first sub-column connection portion 43. The second connection portion 31 is connected to the first sub-column connection portion 43, so as to implement connection between the second connection portion 31 and the first semiconductor device 310. In the second memory cell array 5, the plurality of second semiconductor devices 320 arranged in the first direction form a plurality of second sub-columns 52. The same end of the plurality of second semiconductor devices 320 in each of the second sub-columns 52 is connected to the second sub-column connection portion 53. The third connection portion 32 is connected to the second sub-column connection portion 53, so as to implement connection between the third connection portion 32 and the second semiconductor device 320. In some embodiments, the first sub-column connection portion 43 and the second sub-column connection portion 53 are isolated from each other. The second connection portion 31 and the third connection portion 32 may be respectively disposed on the same side of the first memory cell array 4 and the second memory cell array 5, or may be respectively disposed on different sides of the first memory cell array 4 and the second memory cell array 5. The second connection portion 31 and the third connection portion 32 may each be formed integrally with the first sub-column connection portion 43 and the second sub-column connection portion 53 respectively, or may each be a connection structure that is formed by using a separate process and that is connected to the first sub-column connection portion 43 and the second sub-column connection portion 53. In some embodiments, the second connection portion 31 and the third connection portion 32 may be end regions of the first sub-column connection portion 43 and the second sub-column connection portion 53, respectively.

The plurality of first semiconductor devices 310 arranged in the second direction form a plurality of first sub-rows 44, and the same end of each first semiconductor device 310 in each of the first sub-rows 42 is connected to a first sub-row connection portion 45. In the second memory cell array 5, the plurality of second semiconductor devices 320 arranged in the second direction form a plurality of second sub-rows 54. The same end of each second semiconductor device 320 in each of the second sub-rows 54 is connected to a second sub-row connection portion 55. The first connection portion 30 is at least connected to the first sub-row connection portion 45 or the second sub-row connection portion 55. In some embodiments, the first connection portion 30 may be a structure formed integrally with the first sub-row connection portion 45 and the second sub-column connection portion 55, or may be a connection structure connected to the first sub-row connection portion 45 and/or the second sub-row connection portion 55 by using a separate process. In some embodiments, the first connection portion may be an end region of the first sub-row connection portion 45 and/or the second sub-row connection portion 55.

In some embodiments, the first memory cell array 4 includes a plurality of first sub-column connection portions 43 and a plurality of first sub-row connection portions 45. The quantity of the first sub-column connection portions 43 is greater than that of the first sub-row connection portions 45. In some embodiments, the quantity of the first sub-column connection portions 43 in the first memory cell array 4 may be twice that of the first sub-row connection portions 45. The second memory cell array 5 includes a plurality of second sub-column connection portions 53 and a plurality of second sub-row connection portions 55. The quantity of the second sub-column connection portions 53 is greater than that of the second sub-row connection portions 55. In some embodiments, the quantity of the second sub-column connection portions 53 in the second memory cell array 5 may be twice that of the second sub-row connection portions 55.

In some embodiments, the length by which at least one first sub-column connection portion 43 extends in the first direction is less than that by which at least one first sub-row connection portion 45 extends in the second direction. Similarly, the length by which at least one second sub-column connection portion 53 extends in the first direction is less than that by which at least one second sub-row connection portion 55 extends in the second direction.

In some embodiments, the first memory cell array 4 and the second memory cell array 5 further include a third sub-column connection portion 60. The third sub-column connection portion 60 extends in the first direction and extends from the first memory cell array 4 to the second memory cell array 5. The third sub-column connection portion 60 connects the same ends of the plurality of first semiconductor devices 310 and the plurality of second semiconductor devices 320 that extend in the first direction. In some embodiments, the third sub-column connection portion 60 is disposed at intervals in the second direction with the first sub-column connection portion 43 and the second sub-column connection portion 53.

In some embodiments, the first surface A and/or the second surface B further have/has a connection pad connected to the third sub-column connection portion 60, so as to form a transmission channel that extends one end of each of the plurality of first semiconductor devices and the plurality of second semiconductor devices that extend in the first direction to the surface of the semiconductor structure.

In some embodiments, the first sub-column connection portion 43, the second sub-column connection portion 53, and the third sub-column connection portion 60 are respectively connected to the same end of the first semiconductor device 310 and the second semiconductor device 320. The first sub-row connection portion 45 and the second sub-row connection portion 55 are respectively connected to the other ends of the first semiconductor device 310 and the second semiconductor device 320.

In some embodiments, referring to descriptions in FIG. 1 to FIG. 4, the first semiconductor device 310 and the second semiconductor device 320 each include a gate and a drain. The first sub-column connection portion 43 is connected to the drains of the plurality of first semiconductor devices 310 in the first direction in the first memory cell array 4, and the second sub-column connection 53 is connected to the drains of the plurality of second semiconductor devices 320 in the first direction in the second memory cell array 5. The first sub-row connection portion 45 is connected to the gates of the plurality of first semiconductor devices 310 in the second direction in the first memory cell array 4, and the second sub-row connection portion 55 is connected to the gates of the plurality of second semiconductor devices 320 in the second direction in the second memory cell array 5. The third sub-column connection portion 60 is connected to the drains of the plurality of first semiconductor devices 310 and the plurality of second semiconductor devices 320 in the first direction in the first memory cell array 4 and the second memory cell array 5.

In some embodiments, each sub-row connection portion may also be connected to the gate of each semiconductor device, and each sub-row connection portion may also be connected to the drain of each semiconductor device.

In some embodiments, still referring to FIG. 5, a sixth connection pad 130 and a seventh connection pad 240 are respectively disposed on the first surface A and the second surface B. There is an interconnection structure that extends through the memory cell region 3 between the sixth connection pad 130 and the seventh connection pad 240.

In some embodiments, referring to FIG. 1 to FIG. 4, each first semiconductor device 310 in the first memory cell array 4 further has an electrode portion 3104. Each semiconductor device 310 further has a source. The electrode portion 3104 is connected to the source of each semiconductor device. There are further electrode portions 3105 (not shown in FIG. 5) connected to each other between the semiconductor devices. Each second semiconductor device 320 in the second memory cell array 5 has an electrode portion 3204. Each semiconductor device 320 further has a source. The electrode portion 3204 is connected to the source of each semiconductor device. There are further electrode portions 3205 (not shown in FIG. 5) connected to each other between the semiconductor devices. For connection relationships, between the first surface A and the second surface B, between the electrode portion 3105 and the electrode portion 3205 of each semiconductor device in the semiconductor structure shown in FIG. 5, refer to the descriptions in FIG. 1 to FIG. 4. Details are not described herein again.

In the foregoing embodiment, there may be multiple first memory cell arrays 4 and second memory cell arrays 5, and each memory cell array may be the smallest integrated unit of the semiconductor device array, for example, one MAT (Memory Array Tile).

In some embodiments, the semiconductor structure 1a further includes an interconnection layer 1 and a redistribution layer 2. The interconnection layer 1 is disposed adjacent to the first surface A, and the redistribution layer 2 is disposed adjacent to the second surface B. The memory cell region 3 is disposed between the interconnection layer 1 and the redistribution layer 2. For the interconnection layer 1 and the redistribution layer 2 in the semiconductor structure 1a shown in FIG. 5, refer to the descriptions in FIG. 1 to FIG. 4. Details are not described herein again.

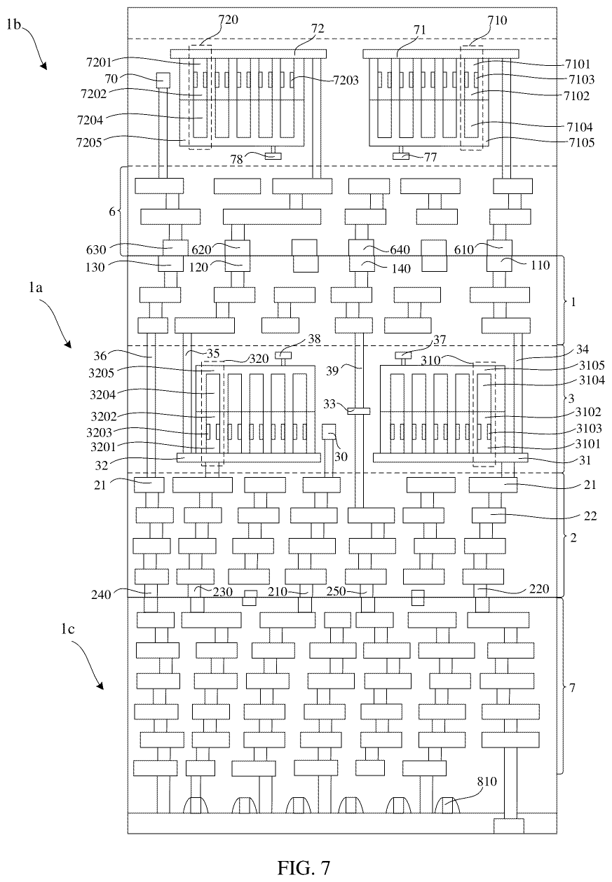

Embodiments of the present disclosure further provide an integrated assembly. Referring to FIG. 7, the integrated assembly includes a first semiconductor structure 1a and a second semiconductor structure 1b. For the first semiconductor structure 1a, refer to the foregoing semiconductor structure 1a and the structures shown in FIG. 1 to FIG. 5. For composition of the second semiconductor structure 1b, refer to FIG. 6. The second semiconductor structure 1b has a first bonding surface C. The first bonding surface C may be a surface exposed by the second semiconductor structure 1b, and is configured to perform bonding with the first semiconductor structure 1a. The second semiconductor structure 1b further includes a memory cell region. The memory cell region has a third semiconductor device 710 and a fourth semiconductor device 720. The third semiconductor device 710 and the fourth semiconductor device 720 may be the same semiconductor device located in the same memory cell array, or may be the same semiconductor device located in different memory cell arrays, for example, are both DRAM memory cells. The third semiconductor device 710 includes a drain 7101, a source 7102, and a gate 7103 located between the source and the drain. The third semiconductor device 710 further includes an electrode portion 7104 and an electrode portion 7105. The electrode portion 7104 is connected to the source 7102. The electrode portion 7104 and the electrode portion 7105 constitute two electrodes of a capacitor. Similarly, the fourth semiconductor device 720 includes a drain 7201, a source 7202, and a gate 7203 located between the drain 7201 and the source 7202. The fourth semiconductor device 720 further includes an electrode portion 7204 and an electrode portion 7205. The electrode portion 7204 is connected to the source 7202. The electrode portion 7204 and the electrode portion 7205 constitute two electrodes of a capacitor.

The second semiconductor structure 1b further includes a connection portion 71 connected to the third semiconductor device 710 and a connection portion 72 connected to the fourth semiconductor device 720. In some embodiments, the connection portion 71 is connected to the drain 7101 of the third semiconductor device 710, and the connection portion 72 is connected to the drain 7201 of the fourth semiconductor device 720. In some other embodiments, the connection portion 71 is connected to the gate of the third semiconductor device 710, and the connection portion 72 is connected to the gate of the fourth semiconductor device 720. The second semiconductor structure 1b further includes a common connection portion 70 connected to the third semiconductor device 710 and/or the fourth semiconductor device 720. In some embodiments, the common connection portion 70 is connected to the gate of the third semiconductor device 710 and/or the gate of the fourth semiconductor device 720. In some other embodiments, the common connection portion 70 may alternatively be connected to the drain of the third semiconductor device 710 and/or the drain of the fourth semiconductor device 720. The second semiconductor structure 1b further includes a connection portion 77 connected to the third semiconductor device 710 and a connection portion 78 connected to the fourth semiconductor device 720. In some embodiments, the connection portion 77 is connected to the electrode portion 7105 of the third semiconductor device 710, and the connection portion 78 is connected to the electrode portion 7205 of the fourth semiconductor device 720. In some embodiments, the connection portion 77 and the connection portion 78 may be connected to each other.

The second semiconductor structure 1b further includes a first bonding surface C. The first bonding surface C may be a surface exposed by the second semiconductor structure 1b. A plurality of connection pads are disposed on the first bonding surface C to perform bonding connection with each connection pad in the first surface A of the first semiconductor structure 1a. A connection layer 6 is further disposed between the first bonding surface C and each of the third semiconductor device 710 and the fourth semiconductor device 720. The connection layer 6 includes at least one metal interconnection layer configured to establish a connection channel between each connection pad in the first bonding surface C and each of the third semiconductor device 710 and the fourth semiconductor device 720. In some embodiments, the quantity of metal interconnection layers in the connection layer 6 is the same as that of layers of the conductive interconnection lines in the interconnection layer 1 in the first semiconductor structure 1a, for example, two. In some embodiments, a non-electrically connected virtual connection pad is further disposed in the first bonding surface C, and the first bonding surface C may be a surface used for hybrid bonding (hybrid bonding) or fusion bonding (Fusion Bonding).

With reference to FIG. 6 and FIG. 7, the following briefly describes connection relationships between each connection pad in the second semiconductor structure 1b and each of the third semiconductor device 710 and the fourth semiconductor device 720, and a connection relationship between the first semiconductor structure 1a and the second semiconductor structure 1b.

In the second semiconductor structure 1b, the connection pad 610 is connected to one connection portion 71 of the third semiconductor device 710, and the connection pad 620 is connected to one connection portion 72 of the fourth semiconductor device 720. The connection pad 630 is connected to the connection portion 70, so that one end of the third semiconductor device 710 and/or one end of the fourth semiconductor device 720 are/is connected to the connection pad 630. The first bonding surface C further includes a connection pad 640, and the connection pad 640 is connected to the connection portion 77 and/or the connection portion 78.

After the first bonding surface C and the first surface A are bonded, the connection pad 610 and the first connection pad 110 are in bonding connection with each other, the connection pad 620 and the second connection pad 120 are in bonding connection with each other, and the connection pad 640 is in bonding connection with the eighth connection pad 140, so as to, between the first semiconductor structure 1a and the second semiconductor structure 1b, form a signal transmission channel between the first semiconductor device 310 and the third semiconductor device 710 and a signal transmission channel between the second semiconductor device 320 and the fourth semiconductor device 720. In some embodiments, these signal transmission channels include a connection channel between the drain of the first semiconductor device 310 and the drain of the third semiconductor device 710, such as a channel between the connection pad 610 and the first connection pad 110, and a connection channel between the drain of the second semiconductor device 320 and the drain of the fourth semiconductor device 720, for example, a channel between the connection pad 620 and the second connection pad 120. The signal transmission channel further includes a channel between the connection pad 640 and the eighth connection pad 140, and the channel may be a connection channel between the electrode portion 3105 of the first semiconductor device 310 and/or the electrode portion 3205 of the second semiconductor device 320 and the electrode portion 7105 of the third semiconductor device 710 and/or the electrode portion 7205 of the fourth semiconductor device 720.

After the first bonding surface C and the first surface A are bonded, the connection pad 630 and the sixth connection pad 130 are in bonding connection with each other to form a signal transmission channel connecting the first semiconductor structure 1a and the second semiconductor structure 1b. In some embodiments, these signal transmission channels may be signal transmission channels of the gate of the third semiconductor device 710 and/or the gate of the fourth semiconductor device 720.

The integrated assembly provided in the embodiments of the present disclosure further includes a third semiconductor structure 1c in bonding connection with a second surface B of the first semiconductor structure 1a. Bonding between the first semiconductor structure 1a and the third semiconductor structure 1c is hybrid bonding (hybrid bonding) or fusion bonding (Fusion Bonding). Still referring to FIG. 7, the third semiconductor structure 1c includes a fifth semiconductor device 810. A routing layer 7 is disposed above the fifth semiconductor device 810. The routing layer 7 is disposed between the second surface B and the fifth semiconductor device 810, and is configured to connect the fifth semiconductor device 810 to each connection pad on the second surface B, thereby establishing signal transmission channels between the third semiconductor structure and each of the first semiconductor structure and the second semiconductor structure, and implementing interconnection between the semiconductor devices.

In some embodiments, the routing layer 7 includes multiple layers of metal wires, and the quantity of the layers of metal wires in the routing layer 7 is greater than that of the conductive redistribution layers in the redistribution layer of the first semiconductor structure.

In some embodiments, the first semiconductor device, the second semiconductor device, the third semiconductor device, and the fourth semiconductor device are the same semiconductor devices, for example, are all DRAM memory devices. The fifth semiconductor device is different from the first semiconductor device, and the fifth semiconductor device may be a logic device. In some embodiments, the first semiconductor structure and the second semiconductor structure may each be a memory structure consisting of a DRAM memory cell, a NAND memory cell, or another memory cell. The first semiconductor structure and the second semiconductor structure include an array of memory cells that can use transistors as switches and selection devices. The third semiconductor structure may be any suitable digital, analog, and/or hybrid signal circuit structure configured to facilitate operation of the memory structure.

It should be noted that, the first semiconductor structure 1a in FIG. 7 takes the first semiconductor structure shown in FIG. 1 as an example. The first semiconductor structure may alternatively be the first semiconductor structure shown in FIG. 2 to FIG. 4. A connection relationship between the first semiconductor structure 1a and each of the second semiconductor structure and the third semiconductor structure can be clearly understood by a person skilled in the art after reading the foregoing description.

A person of ordinary skill in the art may understand that the foregoing implementations are specific embodiments for implementing the present disclosure. In an actual application, various modifications may be made to the forms and details of the implementations without departing from the spirit and scope of the embodiments of the present disclosure. Any person skilled in the art may make changes and modifications without departing from the spirit and scope of the embodiments of the present disclosure. Therefore, the protection scope of the embodiments of the present disclosure shall be subject to the scope defined by the claims.

What is claimed is:

1. A semiconductor structure, comprising:
a first surface and a second surface that are opposite to each other;
a first connection pad and a second connection pad, disposed on the first surface;
a third connection pad, a fourth connection pad, and a fifth connection pad, disposed on the second surface; and
a memory cell region, wherein the memory cell region is disposed between the first surface and the second surface, the memory cell region comprises a first semiconductor device and a second semiconductor device that are arranged in a first direction, the first connection pad and the fourth connection pad are connected to the first semiconductor device, the second connection pad and the fifth connection pad are connected to the second semiconductor device, the memory cell region further comprises a first connection portion, the first connection portion is connected to at least one of the first semiconductor device and the second semiconductor device, and the first connection portion is connected to the third connection pad.

2. The semiconductor structure according to claim 1, wherein in a direction parallel to the first surface, a maximum width of at least one of the first connection pad and the second connection pad is greater than that of at least one of the third connection pad, the fourth connection pad, and the fifth connection pad.

3. The semiconductor structure according to claim 1, wherein in a direction parallel to the first surface, a minimum spacing between the first connection pad and the second connection pad is greater than that between every two connection pads of the third connection pad, the fourth connection pad, and the fifth connection pad.

4. The semiconductor structure according to claim 1, wherein the semiconductor structure further comprises:
an interconnection layer disposed adjacent to the first surface; and
a redistribution layer disposed adjacent to the second surface; wherein
the first connection pad and the second connection pad are respectively connected to the first semiconductor device and the second semiconductor device by using the interconnection layer, the third connection pad is connected to the first connection portion by using the redistribution layer, the fourth connection pad and the fifth connection pad are respectively connected to the first semiconductor device and the second semiconductor device by using the redistribution layer, and metal density of the redistribution layer is greater than that of the interconnection layer.

5. The semiconductor structure according to claim 4, wherein the semiconductor structure further comprises a second connection portion and a third connection portion, the second connection portion is connected to the first semiconductor device, the third connection portion is connected to the second semiconductor device, the first connection pad and the fourth connection pad are connected to the second connection portion, the second connection pad and the fifth connection pad are connected to the third connection portion, the second connection portion, the third connection portion, and the first connection portion are isolated from one another, the redistribution layer comprises a first redistribution layer, and the first connection portion, the second connection portion, and the third connection portion are connected to the first redistribution layer.

6. The semiconductor structure according to claim 1, wherein a sixth connection pad is further disposed on the first surface, a seventh connection pad is further disposed on the second surface, and the sixth connection pad is connected to the seventh connection pad.

7. The semiconductor structure according to claim 4, wherein the semiconductor structure further has a fourth connection portion, the fourth connection portion is located in the memory cell region, and in a region located between the first semiconductor device and the second semiconductor device, an eighth connection pad is further disposed on the first surface, a ninth connection pad is further disposed on the second surface, and the fourth connection portion is connected to the eighth connection pad and the ninth connection pad.

8. The semiconductor structure according to claim 7, wherein the redistribution layer further comprises a second redistribution layer, and the fourth connection portion is connected to the second redistribution layer.

9. A semiconductor structure, comprising:
a first surface and a second surface that are opposite to each other;
a first connection pad and a second connection pad, disposed on the first surface;
a third connection pad, a fourth connection pad, and a fifth connection pad, disposed on the second surface; and
a memory cell region, wherein the memory cell region is disposed between the first surface and the second surface, and comprises a first memory cell array and a second memory cell array that are arranged at an interval, the first memory cell array comprises a plurality of first semiconductor devices arranged in a first direction, and the second memory cell array comprises a plurality of second semiconductor devices arranged in the first direction; wherein
the first connection pad and the fourth connection pad are connected to the first semiconductor device, the second connection pad and the fifth connection pad are connected to the second semiconductor device, the memory cell region further comprises a first connection portion, the first connection portion is connected to at least one of the first semiconductor device and the second semiconductor device, and the third connection pad is connected to the first connection portion.

10. The semiconductor structure according to claim 9, wherein the first memory cell array comprises a second connection portion, the second memory cell array comprises a third connection portion, the second connection portion is connected to the first semiconductor device, the third connection portion is connected to the second semiconductor device, the first connection pad and the fourth connection pad are connected to the second connection portion, and the second connection pad and the fifth connection pad are connected to the third connection portion.

11. The semiconductor structure according to claim 10, wherein the plurality of first semiconductor devices arranged in the first direction form a plurality of first sub-columns, each of the first sub-columns comprises a first sub-column connection portion connected to the plurality of first semiconductor devices in the first direction, the plurality of second semiconductor devices arranged in the first direction form second sub-columns, each of the second sub-columns comprises a second sub-column connection portion connected to the plurality of second semiconductor devices in the first direction, the first connection pad and the fourth connection pad are connected to the first sub-column connection portion by using the second connection portion, the second connection pad and the fifth connection pad are connected to the second sub-column connection portion by using the third connection portion, the first sub-column connection portion and the second sub-column connection portion are extended and arranged in the first direction, the first sub-column connection portion and the second sub-column connection portion are isolated from each other, the first memory cell array further comprises a plurality of first semiconductor devices arranged in a second direction, the second memory cell array further comprises a plurality of second semiconductor devices arranged in the second direction, the plurality of first semiconductor devices arranged in the second direction form a plurality of first sub-rows, the plurality of second semiconductor devices arranged in the second direction form a plurality of second sub-rows, each of the first sub-rows comprises a first sub-row connection portion connected to the plurality of first semiconductor devices in the second direction, each of the second sub-rows comprises a second sub-row connection portion connected to the plurality of second semiconductor devices in the second direction, the first sub-row connection portion and the second sub-row connection portion are extended and arranged in the second direction, and the first connection portion is connected to at least one of the first sub-row connection portion and the second sub-row connection portion.

12. The semiconductor structure according to claim 11, wherein the first memory cell array comprises a plurality of first sub-column connection portions and a plurality of first sub-row connection portions, a quantity of the first sub-column connection portions is greater than that of the first sub-row connection portions, the second memory cell array comprises a plurality of second sub-column connection portions and a plurality of second sub-row connection portions, and a quantity of the second sub-column connection portions is greater than that of the second sub-row connection portions.

13. The semiconductor structure according to claim 11, wherein the memory cell region further comprises a third sub-column connection portion that extends in the first direction, the third sub-column connection portion extends from the first memory cell array to the second memory cell array, and the third sub-column connection portion is connected to the plurality of first semiconductor devices and the plurality of second semiconductor devices that extend in the first direction.

14. The semiconductor structure according to claim 13, wherein the first semiconductor device and the second semiconductor device each comprise a gate and a drain, the first sub-row connection portion is connected to the gate of the first semiconductor device, the second sub-row connection portion is connected to the gate of the second semiconductor device, the first sub-column connection portion is connected to the drain of the first semiconductor device, the second sub-column connection portion is connected to the drain of the second semiconductor device, and the third sub-column connection portion is connected to the drains of the first semiconductor device and the second semiconductor device.

15. The semiconductor structure according to claim 9, wherein a sixth connection pad is further disposed on the first surface, a seventh connection pad is further disposed on the second surface, and the sixth connection pad is connected to the seventh connection pad.

16. An integrated assembly, comprising:
a first semiconductor structure, wherein the first semiconductor structure comprises a first surface, a first connection pad and a second connection pad are disposed on the first surface, the first semiconductor structure further comprises a memory cell region, the memory cell region is disposed below the first surface, the memory cell region comprises a first semiconductor device and a second semiconductor device, the first connection pad is connected to the first semiconductor device, the second connection pad is connected to the second semiconductor device, and a first connection portion is disposed between the first semiconductor device and the second semiconductor device; and
a second semiconductor structure, wherein the second semiconductor structure has a first bonding surface in bonding connection with the first surface of the first semiconductor structure, the second semiconductor structure comprises a third semiconductor device and a fourth semiconductor device, the third semiconductor device and the first semiconductor device are connected to the first connection pad by using the first bonding surface, the fourth semiconductor device and the second semiconductor device are connected to the second connection pad by using the first bonding surface, the second semiconductor structure further has a common connection portion, and the common connection portion is at least connected to the third semiconductor device or the fourth semiconductor device; wherein
the first semiconductor structure further comprises a second surface, a third connection pad, a fourth connection pad, a fifth connection pad, and a sixth connection pad are disposed on the second surface, the third connection pad is connected to the first connection portion, the fourth connection pad is connected to the first connection pad, the fifth connection pad is connected to the second connection pad, and the sixth connection pad is connected to the common connection portion.

17. The assembly according to claim 16, wherein the first semiconductor structure further comprises an interconnection layer, the interconnection layer is located between the first surface and the second surface and disposed adjacent to the first surface, the second semiconductor structure further comprises a connection layer disposed adjacent to the first bonding surface, and the third semiconductor device and the fourth semiconductor device are interconnected to the first semiconductor device and the second semiconductor device by using the connection layer.

18. The assembly according to claim 16, further comprising a third semiconductor structure, wherein one surface of the third semiconductor structure is in bonding connection with the second surface of the first semiconductor structure, the third semiconductor structure comprises a fifth semiconductor device, the first semiconductor structure further comprises a redistribution layer disposed adjacent to the second surface, the third semiconductor structure comprises a routing layer disposed adjacent to the second surface, the first semiconductor device, the second semiconductor device, the third semiconductor device, and the fourth semiconductor device are interconnected to the fifth semiconductor device by using the routing layer.
